(19) United States
(12) Patent Application Publication
(10) Pub. No.: US 2007/0029610 A1
(43) Pub. Date: Feb. 8, 2007

(54) NON-VOLATILE MEMORY AND FABRICATING METHOD THEREOF

(76) Inventors: Houng-Chi Wei, Hsinchu City (TW); Saysamone Pittikoun, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/164,138

(22) Filed: Nov. 11, 2005

(30) Foreign Application Priority Data
Aug. 8, 2005 (TW) 94126669

(51) Int. Cl. H01L 29/76; H01L 29/94; H01L 31/00

(52) U.S. Cl. 257/345

(57) ABSTRACT

A non-volatile memory and fabricating method thereof are provided. First, a plurality of raised bit lines is formed on the substrate. The raised bit lines are paralleled one another, and extended in the same direction. Then, a charge trap layer is formed on the substrate. Afterwards, a plurality of word lines paralleled to one another is formed on the raised bit lines and filled up the gaps between the raised bit lines. Besides, the word lines are extended in another direction crossed by the direction of the raised bit lines. Because the non-volatile memory adopts design of raised bit lines, dopant diffusion induced by thermal processes of the buried bit lines can be avoided.

### CROSS-REFERENCE TO RELATED APPLICATION

This application claims the priority benefit of Taiwan application serial no. 94126669, filed on Aug. 08, 2005. All disclosure of the Taiwan application is incorporated herein by reference.

### BACKGROUND OF THE INVENTION

1. Field of Invention

The present invention relates to the structure and fabricating method of a semiconductor device. More particularly, the present invention relates to the structure and fabricating method of a non-volatile memory.

2. Description of Related Art

Among various types of non-volatile memory products, electrically erasable programmable read only memory (EEPROM) is a memory device that has been widely used in personal computers and electronic equipment. Data can be stored, read out or erased from the EEPROM many times and stored data are retained even after power supplying the devices is cut off.

The typical EEPROM has floating gate and control gate fabricated of doped polysilicon. However, current leakage will be occurred in the device and the reliability of the device will be affected when there is defect in the tunneling oxide under the doped polysilicon floating gate layer.

Accordingly, in conventional technologies, sometimes the polysilicon floating gate is replaced by a charge trapping layer whose material is, for example, silicon nitride. Generally, there is respectively a layer of silicon oxide on both of the top and underneath of the silicon nitride charge trapping layer to form an oxide-nitride-oxide (ONO) composite layer. This kind of devices is generally called silicon-oxide-nitride-oxide-silicon (SONOS) device or nitride read-only memory (NROM).

SONOS devices or NROM may adopt virtual ground memory architecture. The virtual ground memory architecture may increase the density of cell array and is compatible with conventional process of semiconductor. However, the virtual ground memory architecture uses buried source/drain doped region as bit lines (buried bit lines). Under the requirements of reduced device size and high integration, when the space between two adjacent buried bit lines is reduced, the dopant diffusion in the two adjacent buried bit lines will cause the channel between these two bit lines to decrease, which may result in abnormal electrical penetration between the two adjacent buried bit lines.

To solve the problem mentioned above, a pocket doped region is introduced into conventional technology to be used as the dopant isolation region of the buried bit lines. That is, performing pocket ion implantation using the same mask pattern to form the pocket doped region, then performing ion implantation to form the buried bit lines. The dopant thermal diffusion problem of buried bit lines is prevented by wrapping the bit lines with the pocket doped region. However, pocket doped region has to use the more complex large angle implantation; if the result of wrapping the buried bit lines is not good enough, punch-through will be occurred. As the size of devices is getting smaller and smaller, the length of channels has to be reduced accordingly; thus, the difficulty of photolithography of the pocket doped region and the method for improvement thereof will increase as well.

### SUMMARY OF THE INVENTION

Accordingly, an aspect of the present invention is directed to provide a non-volatile memory with raised bit line structure, which may avoid dopant diffusion induced during the annealing process of the doped region effectively, thus the design of the device's size may not be limited and may be reduced further to increase the integration of memory devices.

According to the present invention, a non-volatile memory is provided. The non-volatile memory has a plurality of raised bit lines formed on the substrate in parallel and extended in the first direction, and a plurality of word lines. These word lines are extended in the second direction in parallel and are spanned over these raised bit lines; and the first direction is crossed by the second direction. In addition, a charge trapping layer is disposed under the word lines and stops dopant transverse diffusion of these bit lines induced during the annealing process of the doped region in the second direction.

According to the non-volatile memory in the embodiment of the present invention, the non-volatile memory further includes a top dielectric layer disposed between the word lines and the charge trapping layer.

According to the non-volatile memory in the embodiment of the present invention, the non-volatile memory further includes a bottom dielectric layer disposed between the charge trapping layer and the raised bit lines, and between the charge trapping layer and the substrate.

According to the non-volatile memory in the embodiment of the present invention, a plurality of trenches is disposed on the substrate between these raised bit lines.

According to the non-volatile memory in the embodiment of the present invention, the non-volatile memory further includes a plurality of doped regions disposed respectively on the sidewalls of the trenches.

According to the non-volatile memory in the embodiment of the present invention, the non-volatile memory further includes an insulating layer disposed between the word lines and the raised bit lines.

According to the non-volatile memory in the embodiment of the present invention, the material of the raised bit lines includes doped monocrystalline silicon and doped epitaxial silicon.

According to the non-volatile memory in the embodiment of the present invention the material of the word lines includes conductive material which includes one of doped polysilicon and polycides.

The present invention further provides a fabricating method of a non-volatile memory. A substrate is provided first, then a plurality of raised bit lines, which are paralleled and extended in the first direction, are formed on the substrate. Next, a charge trapping layer is formed on the substrate which covers these raised bit lines and the substrate. After that, a plurality of word lines is formed on the substrate. The word lines are extended in the second direction in parallel and are spanned over these raised bit lines. In addition, the second direction is crossed by the first direction. Wherein, the charge trapping layer stops dopant transverse diffusion of these raised bit lines induced during the annealing process of the doped region in the second direction.

According to an exemplary embodiment of the present invention, a fabricating method of a non-volatile memory is provided, wherein the steps of forming the raised bit lines on the substrate include forming a dielectric layer on the substrate first; patterning the dielectric layer to form a plurality of openings extending in the first direction; forming the raised bit lines on the openings, respectively; and removing the dielectric layer.

According to the fabricating method of a non-volatile memory in the embodiment of the present invention, the material of the raised bit lines includes doped epitaxial silicon; and the formation method of the doped epitaxial silicon includes chemical vapor deposition.

According to the fabricating method of a non-volatile memory in the embodiment of the present invention, the steps of forming raised bit lines on the substrate include forming an insulating layer on the substrate first; forming the first doped region on the substrate; patterning the insulating layer and the substrate; and forming a plurality of trenches extending in the first direction on the substrate. Wherein, the depth of the trenches is greater than the depth of the first doped region.

According to the fabricating method of a non-volatile memory in the embodiment of the present invention, the method of forming the first doped region on the substrate includes Ion Implantation.

According to the fabricating method of a non-volatile memory in the embodiment of the present invention, the fabricating method of a non-volatile memory provided further includes forming a plurality of second doped regions on the sidewalls of the trenches, and the method of forming these second doped regions includes tilt angle ion implantation.

According to the fabricating method of a non-volatile memory in the embodiment of the present invention, the method of forming the charge trapping layer on the substrate includes chemical vapor deposition.

According to the fabricating method of a non-volatile memory in the embodiment of the present invention, the fabricating method of a non-volatile memory further includes forming a bottom dielectric layer after the step of forming the raised bit lines and before the step of forming the charge trapping layer, and the method of forming the bottom dielectric layer includes thermal oxidation or chemical vapor deposition.

According to the fabricating method of a non-volatile memory in the embodiment of the present invention, the fabricating method of a non-volatile memory further includes forming a top dielectric layer on the charge trapping layer after the step of forming the charge trapping layer and before the step of forming the word lines, and the method of forming the top dielectric layer includes chemical vapor deposition.

According to the fabricating method of a non-volatile memory in the embodiment of the present invention, the method of forming the word lines on the substrate includes forming a conductive material layer on the substrate first, and then patterning the conductive material layer.

In overview, according to the present invention, since the design of the raised bit lines is used in the fabricating method of the non-volatile memory, and the charge trapping layer is used for stopping the transverse dopant diffusion effect of these raised bit lines, thereby dopant diffusion induced by annealing after doping or other thermal processes of the buried bit lines can be avoided. Moreover, to the substrate between the raised bit lines, trench structure is disposed and the channel length between the raised bit lines can be adjusted according to the depth of the trenches, so that enough channel length can be maintained to prevent short channel effect. Thereby, the size of the device can be reduced dramatically without being restricted by the dopant diffusion problem; and the integration of memory devices may be increased accordingly.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of a non-volatile memory according to an exemplary embodiment of the present invention.

FIG. 1B is a cross-section view of FIG. 1A along line I-I′.

FIGS. 2A to 2D are the fabricating flowchart of a non-volatile memory according to an exemplary embodiment of the present invention.

FIG. 3A is a top view of a non-volatile memory according to another exemplary embodiment of the present invention.

FIG. 3B is a cross-section view of FIG. 3A along line II-II′.

FIGS. 4A to 4D are the fabricating flowchart of a non-volatile memory according to another exemplary embodiment of the present invention.

### DESCRIPTION OF EMBODIMENTS

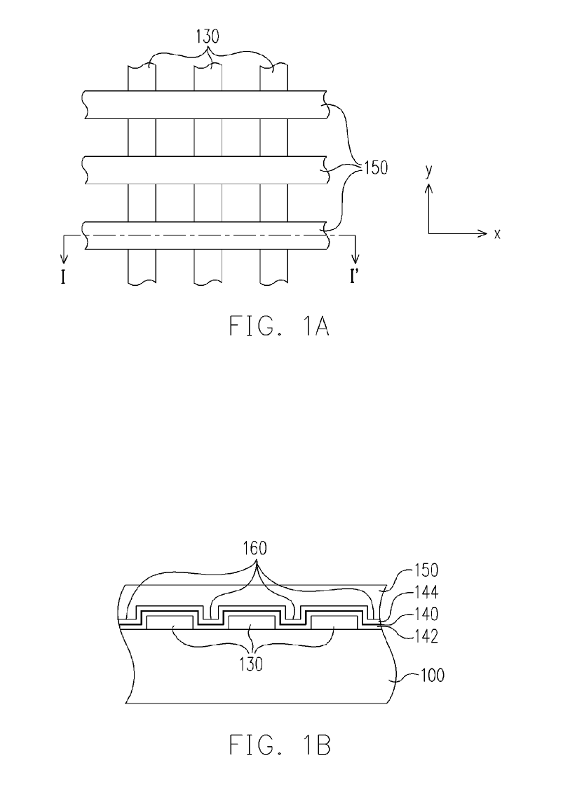

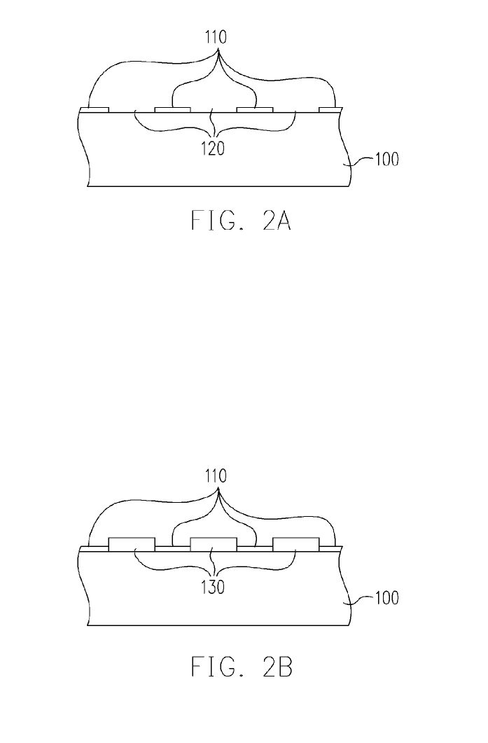

FIG. 1A is a top view of a non-volatile memory according to an embodiment of the present invention and FIG. 1B is a cross-section view of FIG. 1A along line I-I′. Please refer to these two figures.

This non-volatile memory includes a substrate 100, a plurality of raised bit lines 130, a plurality of word lines 150, a bottom dielectric layer 142, a charge trapping layer 140 and a top dielectric layer 144.

Wherein, a plurality of raised bit lines 130 is disposed on the substrate 100 in parallel and is extended in direction y. In addition, the material of the raised bit lines 130 is, for example, doped monocrystalline silicon or doped epitaxial silicon.

A plurality of word lines 150 is extended in direction x in parallel and is spanned over the raised bit lines 130. In addition, direction x is crossed by direction y. The word lines 150 fill up the gaps 160 between the raised bit lines 130. In addition, the material of the word lines 150 is, for example, conductive material including one of doped polysilicon and polycides.

On the other hand, a bottom dielectric layer 142, a charge trapping layer 140 and a top dielectric layer 144 are formed sequentially between the word lines 150 and the substrate 100, and between word lines 150 and the raised bit lines 130. Wherein, the bottom dielectric layer 142 is, for example, a tunneling dielectric layer and the material thereof is, for example, silicon oxide. The material of the charge trapping layer 140 is, for example, silicon nitride. The charge trapping layer 140 stops dopant transverse diffusion of these raised bit lines 130 induced during the annealing process of the doped region in direction x. The top dielectric layer 144 is, for example, a charge barrier layer and the material thereof is, for example, silicon oxide.

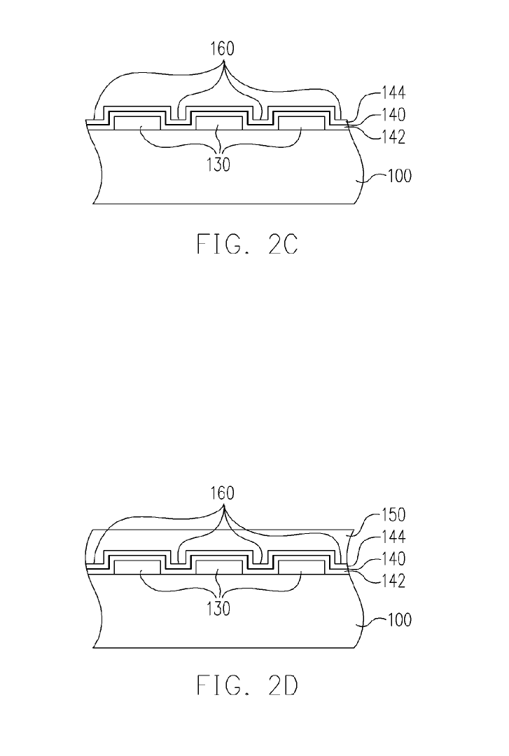

The fabricating flow of the non-volatile memory provided by the present invention is described below. First, referring to FIG. 2A, a substrate 100 is provided. The substrate 100 is, for example, n-substrate or p-substrate. Next, a dielectric layer (not shown) is formed on the substrate 100, and the dielectric layer is patterned to form a plurality of dielectric layers 110 and openings 120; wherein the dielectric layers 110 and the openings 120 are both extended in direction y.

Next, referring to FIG. 2B, raised bit lines 130 are formed on each aperture 120 respectively. The material of the raised bit lines 130 is, for example, doped epitaxial silicon; the formation method of doped epitaxial silicon is, for example, chemical vapor deposition including selective epitaxial growth (SEG), and doped gas, e.g. phosphine (PH₃), is introduced during the deposition process.

Next, referring to FIG. 2C, the dielectric layer 100 is removed and the raised bit lines 130 arranged in parallel and extended in direction y on substrate 100 are remained. After that, a bottom dielectric layer 142 is formed on the substrate 100, wherein the formation method of the bottom dielectric layer 142 is, for example, thermal oxidation or chemical vapor deposition. The material of the bottom dielectric layer 142 is, for example, silicon oxide. Next, a charge trapping layer 140 is formed on the bottom dielectric layer 142 covering the raised bit lines 130 and the substrate 100. Wherein, the material of the charge trapping layer 140 is, for example, silicon nitride. After that, a top dielectric layer 144 is formed on the charge trapping layer 140; wherein, the material of the top dielectric layer 144 is, for example, silicon oxide. In addition, the method of forming the above-mentioned charge trapping layer 140 and top dielectric layer 144 is, for example, chemical vapor deposition.

After that, referring to FIG. 2D, a plurality of word lines 150 is formed on the substrate 100; the formation method of word lines 150 is, for example, forming a conductive material layer (not shown) on the substrate 100 first, and then patterning the conductive material layer. The conductive material layer is, for example, polycides. The word lines 150 are extended in direction x in parallel and spanned over the raised bit lines 130. The word lines 150 fill up the gaps 160 between the raised bit lines 130. The aforesaid direction y is crossed by the direction x.

It is noticeable that, the charge trapping layer 140 stops dopant transverse diffusion of these raised bit lines 130 induced during the annealing process of the doped region in direction x.

Because of the design of the raised bit lines 130 in the non-volatile memory provided by the present invention, the ion distribution range after annealing process may be controlled effectively and the dopant diffusion induced during annealing process after doping or other thermal processes of the buried bit lines can be avoided.

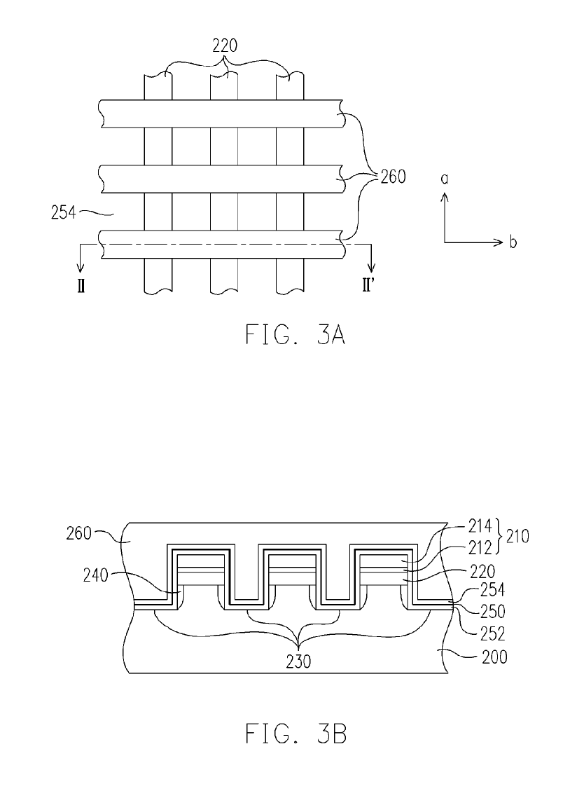

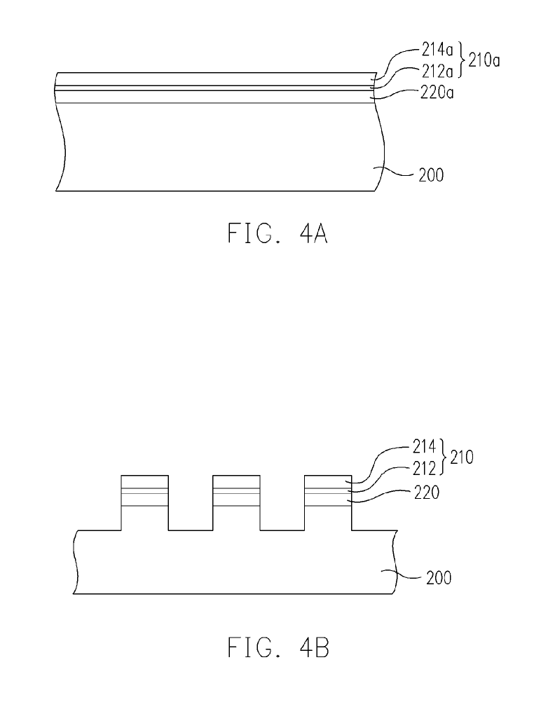

FIG. 3A is a top view of a non-volatile memory according to another embodiment of the present invention and FIG. 3B is a cross-section view of FIG. 3A along line II-II′. Please refer to these two figures.

This non-volatile memory is included a substrate 200, a plurality of raised bit lines 220, a plurality of word lines 260, an insulating layer 210, a bottom dielectric layer 252, a charge trapping layer 250 and atop dielectric layer 254. Compared to FIG. 1B of the first embodiment, the structure of FIG. 3B is further disposed with a plurality of trenches 230 and a plurality of doped regions 240. In addition, in FIG. 3A, the direction of raised bit lines 220 is referred to as direction a, and the direction of word lines 260 is referred to as direction b. Wherein, direction b is crossed by direction a.

Wherein, a plurality of trenches 230 is disposed in parallel in the substrate 200 and extended in direction a.

In addition, the raised bit lines 220 are disposed in parallel in the substrate 200 and are extended in direction a; moreover, the material of the raised bit lines 220 is, for example, doped monocrystalline silicon or doped epitaxial silicon.

Moreover, a plurality of word lines 260 is extended in parallel in direction b and is spanned over the raised bit lines 220. Wherein, direction b is crossed by direction a. In addition, the word lines 260 fill up the inside of the trenches 230 between the raised bit lines 220. On the other hand, the material of the word lines 260 is, for example, conductive material including one of doped polysilicon and polycides.

In addition, the insulating layer 210 is located on the raised bit lines 220. The insulating layer 210 includes, for example, a silicon oxide layer 212 and a silicon nitride layer 214 located above the silicon oxide layer.

On the other hand, a bottom dielectric layer 252, a charge trapping layer 250 and a top dielectric layer 254 are formed from bottom to top sequentially on the surface of the word lines 260 and the trenches 230, and between the word lines 260 and the insulating layer 210. Wherein, the bottom dielectric layer 252 is, for example, a tunneling dielectric layer; the material thereof is, for example, silicon oxide. The material of the charge trapping layer 250 is, for example, silicon nitride. The charge trapping layer 250 stops dopant transverse diffusion of these raised bit lines 220 induced during the annealing process of the doped region in direction b. The top dielectric layer 254 is, for example, a charge barrier layer; the material thereof is, for example, silicon oxide.

Moreover, a plurality of doped regions 240 is disposed in the substrate 200 at the sidewalls of the trenches 230; and the doped regions 240 are, for example, lightly doped drain, so that in design of smaller size, short channel effect or hot electron effect may be reduced.

Because of the design of the raised bit lines 220 in the non-volatile memory provided by the present invention, the ion distribution range of the bit lines after annealing process may be controlled effectively and the dopant diffusion induced during annealing process after doping or other thermal processes in conventional technology may be avoided. Moreover, a plurality of trenches 230 is disposed in the substrate 200 between the raised bit lines 220; and a plurality of doped regions 240 may be disposed at the sidewalls of the trenches 230.

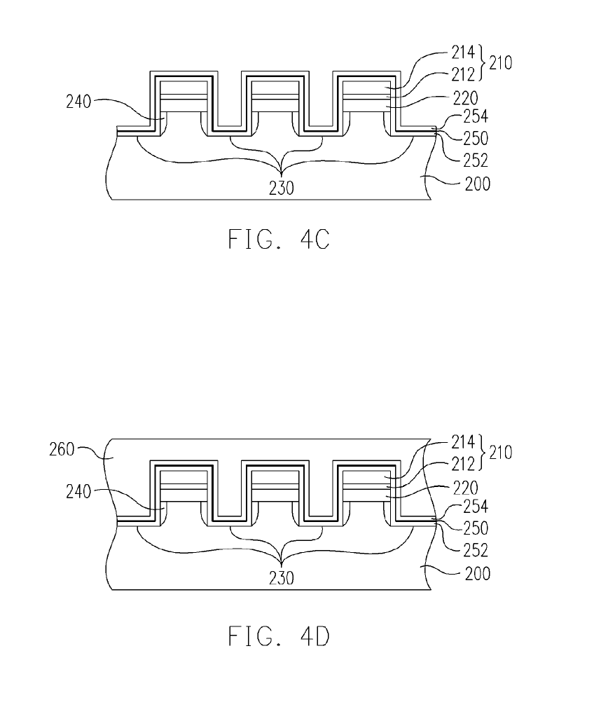

The fabricating flow of a non-volatile memory according to the present invention is described below. Referring to FIG. 4A, first, a substrate 200 is provided which is, for example, n-substrate or p-substrate. Then, an insulating layer 210a is formed on the substrate 200. Wherein, the steps of forming the insulating layer 210a are, for example, deposing silicon oxide layer 212a and silicon nitride layer 214a one by one, then forming the doped region 220a in the substrate. The formation method is, for example, ion implantation.

Next, referring to FIG. 4B, the insulating layer 210a is patterned to form the insulating layer 210. Wherein, the insulating layer 210 includes the silicon oxide layer 212 and the silicon nitride layer 214. In addition, the silicon oxide layer 212 is, for example, a pad oxide while the silicon nitride layer 214 is, for example, a pad nitride. Then part of the substrate 200 is removed using the insulating layer 210 as mask to form trenches 230 and raised bit lines 220. Wherein, the trenches 230, the insulating layer 210 and the raised bit lines 220 are all extended in direction a.

Please refer to FIG. 4C. In an exemplary embodiment, further include forming a plurality of doped regions 240 at the sidewalls of the trenches 230 after forming the trenches 230; the formation method thereof is, for example, tilt angle ion implantation. Wherein, the object of forming the doped regions 240 is to prevent short channel effect or hot electron effect which may happen between the raised bit lines 220 at the sides of the trenches 230. Next, a bottom dielectric layer 252, a charge trapping layer 250 and a top dielectric layer 254 are formed sequentially. Wherein, the formation method of the bottom dielectric layer 252 is, for example, thermal oxidation or chemical vapor deposition while the material of the formed bottom dielectric layer 252 is, for example, silicon oxide. The charge trapping layer 250 covers the raised bit lines 220 and the substrate 200. The formation method of the charge trapping layer 250 and the top dielectric layer 254 is, for example, chemical vapor deposition. The material of the charge trapping layer 250 is, for example, silicon nitride while the material of the top dielectric layer 254 is, for example, silicon oxide.

After that, referring to FIG. 4D, a plurality of word lines 260 is formed on the substrate 200 extending in direction b in parallel. Direction b is crossed by the aforesaid direction a. The word lines 260 are spanned over the raised bit lines 220. The word lines 260 fill up the inside of the trenches 230 between the raised bit lines 220. The formation method of the word lines 260 is, for example, forming a conductive material layer (not shown) on the substrate 200 first, and then patterning it; wherein, the material of the conductive material layer is, for example, one of doped polysilicon and polycides.

It is noticeable that, the charge trapping layer 250 stops dopant transverse diffusion of these raised bit lines 220 induced during the annealing process of the doped region in direction b.

In overview, because of the design of raised bit lines in the non-volatile memory provided by the present invention, the ion distribution range of the bit lines after annealing process may be controlled effectively and dopant diffusion induced during annealing process after doping or other thermal processes of the buried bit lines can be avoided. Moreover, because of the design of disposed trench structures in the substrate between the raised bit lines, the channel length between the raised bit lines can be adjusted according to the depth of the trenches. Accordingly, the size of the device can be reduced dramatically and will not be limited by the dopant diffusion problem, so that the integration of memory devices may be increased.

While the present invention has been particularly shown and described with reference to exemplary embodiments thereof, it will be understood by those of ordinary skill in the art that various changes in form and details may be made therein without departing from the spirit and scope of the present invention as defined by the following claims.
What is claimed is:

1. A non-volatile memory, comprising:
a substrate;
a plurality of raised bit lines disposed in parallel on the substrate and extended in the first direction;
a plurality of word lines extended in a second direction in parallel and spanned over the raised bit lines, the first direction is crossed by the second direction; and
a charge trapping layer disposed under the word lines to stop the dopant diffusion of the raised bit lines in the second direction.

2. The non-volatile memory of claim 1, further comprises a top dielectric layer disposed between the word lines and the charge trapping layer.

3. The non-volatile memory of claim 1, further comprises a bottom dielectric layer disposed between the charge trapping layer and the raised bit lines, and between the charge trapping layer and the substrate.

4. The non-volatile memory of claim 1, wherein a plurality of trenches is disposed in the substrate between the raised bit lines.

5. The non-volatile memory of claim 4, further comprises a plurality of doped regions disposed respectively at the sidewalls of the trenches.

6. The non-volatile memory of claim 1, further comprises an insulating layer disposed between the word lines and the raised bit lines.

7. The non-volatile memory of claim 1, wherein the material of the raised bit lines comprises doped monocrystalline silicon.

8. The non-volatile memory of claim 1, wherein the material of the raised bit lines comprises doped epitaxial silicon.

9. The non-volatile memory of claim 1, wherein the material of the word lines comprises conductive material.

10. The non-volatile memory of claim 1, wherein the material of the word lines comprises one of doped polysilicon and polycides.

11. A fabricating method of a non-volatile memory, comprising:
providing a substrate;
forming a plurality of raised bit lines on the substrate which are arranged in parallel and extended in a first direction;
forming a charge trapping layer covering the word lines and the substrate; and
forming a plurality of word lines on the substrate which are extended in a second direction in parallel and are spanned over the raised bit lines, the first direction is crossed by the second direction, wherein the charge trapping layer stops dopant diffusion of the raised bit lines in the second direction.

12. The method of claim 11, wherein the steps of forming the raised bit lines on the substrate comprise:
forming a dielectric layer on the substrate;
patterning the dielectric layer to form a plurality of openings extending in the first direction;
forming the raised bit lines on the openings respectively; and
removing the dielectric layer.

13. The method of claim 12, wherein the material of the raised bit lines comprises doped epitaxial silicon.

14. The method of claim 13, wherein the formation method of doped epitaxial silicon comprises chemical vapor deposition.

15. The method of claim 11, wherein the steps of forming the raised bit lines on the substrate comprise:
forming an insulating layer on the substrate;
forming a first doped region in the substrate; and
patterning the insulating layer and the substrate, and forming a plurality of trenches extending in the first direction in the substrate, the depth of the trenches is greater than the depth of the first doped region.

16. The method of claim 15, wherein the method of forming the first doped region in the substrate comprises ion implantation.

17. The method of claim 15, further comprises forming a plurality of second doped regions at the sidewalls of the trenches.

18. The method of claim 17, wherein the method of forming the second doped regions at the sidewalls of the trenches comprises tilt angle ion implantation.

19. The method of claim 11, wherein the method of forming the charge trapping layer on the substrate comprises chemical vapor deposition.

20. The method of claim 11, further comprises forming a bottom dielectric layer on the substrate after the step of forming the raised bit lines and before the step of forming the charge trapping layer.

21. The method of claim 20, wherein the method of forming the bottom dielectric layer on the substrate comprises thermal oxidation or chemical vapor deposition.

22. The method of claim 11, further comprises forming a top dielectric layer on the charge trapping layer after the step of forming the charge trapping layer and before the step of forming the word lines.

23. The method of claim 22, wherein the method of forming the top dielectric layer on the charge trapping layer comprises chemical vapor deposition.

24. The method of claim 22, wherein the method of forming the word lines on the substrate comprises:
forming a conductive material layer on the substrate; and
patterning the conductive material layer.
